(19) United States
(12) Patent Application Publication
(10) Pub. No.: US 2025/0393236 A1
(43) Pub. Date: Dec. 25, 2025

(54) SEMICONDUCTOR STRUCTURE, SEMICONDUCTOR DEVICE, AND METHOD OF MANUFACTURING SEMICONDUCTOR STRUCTURE

(71) Applicant: TAIWAN SEMICONDUCTOR MANUFACTURING COMPANY LTD., HSINCHU (TW)

(72) Inventors: RUEI-JYUN HSU, HSINCHU CITY (TW); WEI-JEN CHANG, MIAOLI COUNTY (TW); YU-CHIEN LAI, HSINCHU COUNTY (TW); CHIA-CHI HO, HSINCHU COUNTY (TW); CHUNG-SHIH CHIANG, HSINCHU COUNTY (TW)

(21) Appl. No.: 18/749,654

(22) Filed: Jun. 21, 2024

(51) Int. Cl. H01L 29/778; H01L 29/20; H01L 29/66

(52) U.S. Cl. CPC H10D 30/475; H10D 30/015; H10D 62/8503

(57) ABSTRACT

A semiconductor structure, a semiconductor device, and a method of manufacturing the semiconductor structure are provided. The semiconductor structure includes a first semiconductor layer, a second semiconductor layer, and a third semiconductor layer. The first semiconductor layer includes a first material having a first bandgap. The second semiconductor layer is disposed on the first semiconductor layer, wherein the second semiconductor layer comprises a second material having a second bandgap, wherein the second bandgap is greater than the first bandgap, thus forming a carrier channel in the first semiconductor layer. The third semiconductor layer at least partially overlaps the second semiconductor layer, wherein the first semiconductor layer and the third semiconductor layer have a same material, but have different doping concentrations.

### BACKGROUND

Polysilicon resistors have been widely used in conventional integrated circuit design, including for electrostatic discharge (ESD) protection, resistor-capacitor (RC) oscillators, current resistance limitation, radio-frequency (RF) post drivers, on-chip termination, impedance matching, and other applications. For replacement gate technology (also referred to as gate-last process), the polysilicon resistor typically includes a silicide region, which exhibits lower than desirable resistivity, and accordingly requires higher than desirable area overhead. A single-crystalline silicon resistor (e.g., a resistor formed in a semiconductor substrate) has been proposed to resolve this issue; however, the single-crystalline silicon resistor occupies a large footprint in the integrated circuit.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic top view of a portion of a semiconductor device illustrating some embodiments of the present disclosure that include a resistive element having a meandering serpentine-like pattern disposed between two other electronic components of the semiconductor device.

FIG. 2 is a circuit diagram of a portion of a semiconductor device illustrating some embodiments of the present disclosure that include an electrostatic discharge (ESD) protection circuit, in accordance with some embodiments of the present disclosure.

FIG. 3 is a schematic cross-sectional view taken along a line A-A′ of the semiconductor device in FIG. 1.

FIG. 4 is a perspective view of a portion of the semiconductor device of FIG. 1.

FIG. 5 is a perspective view of a substrate, a first semiconductor layer, a second semiconductor layer, and an isolation feature, in accordance with some embodiments of the present disclosure.

FIG. 6 is a schematic cross-sectional view of a resistive element in a partial-depletion mode where carriers under a third semiconductor layer are partially depleted from a carrier channel, in accordance with some embodiments of the present disclosure.

FIG. 7 is a schematic cross-sectional view of a resistive element in a full-depletion mode where carriers under a third semiconductor layer are fully depleted from a carrier channel, in accordance with some embodiments of the present disclosure.

FIG. 8 is a schematic cross-sectional view of a resistive element in a shunt mode where carriers are fully depleted from a carrier channel, in accordance with some embodiments of the present disclosure.

FIG. 9 is a schematic cross-sectional view of a resistive element in a shunt mode where carriers are partially depleted from a carrier channel, in accordance with some embodiments of the present disclosure.

FIG. 10 is a schematic top view of a resistive element, in accordance with some embodiments of the present disclosure.

FIG. 11 is a schematic top view of a resistive element, in accordance with some embodiments of the present disclosure.

FIG. 12 is a schematic cross-sectional view taken along a line B-B′ of the semiconductor device in FIG. 11.

FIG. 13 is a schematic top view of a resistive element, in accordance with some embodiments of the present disclosure.

FIG. 14 is a schematic top view of a resistive element, in accordance with some embodiments of the present disclosure.

FIG. 15 is a schematic cross-sectional view of a resistive element, in accordance with some embodiments of the present disclosure.

FIG. 16 is a schematic cross-sectional view of a resistive element, in accordance with some embodiments of the present disclosure.

FIG. 17 is a flowchart of a method of manufacturing a resistive element, in accordance with some embodiments of the present disclosure.

FIGS. 18 to 22 are cross-sectional views of intermediate stages of the method of manufacturing a resistive element, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for a purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A group III-V electronic device utilizes a junction between two materials with different bandgaps as a channel. For example, an AlGaN/GaN electronic device is a heterojunction device that is able to operate at higher frequencies than an ordinary electronic device. In the group III-V electronic device, a bandgap discontinuity between two different materials forms a quantum well-like structure, which accommodates a two-dimensional electron gas (2DEG) and results in an increased sheet carrier concentration at the heterojunction interface, which is able to satisfy demands of high power/frequency devices. A p-GaN is disposed to at least partially overlap the AlGaN overlying GaN, and a positive/negative bias may be applied to the group III-V electronic device through the p-GaN, to thereby alter the carrier concentration at the heterojunction interface. The group III-V electronic device including the p-GaN, having an effective resistance same as that of an ordinary resistor, may have a footprint smaller than a footprint of the ordinary resistor. For example, the group III-V electronic device may have a footprint of about one-sixth a size of a footprint of the crystalline silicon resistor. The group III-V electronic device (including the p-GaN and having a tunable bias) that has a same pattern from a top-view perspective as the ordinary resistor may provide a variable resistance between about one-sixth and about 10 times of an effective resistance of the crystalline silicon resistor.

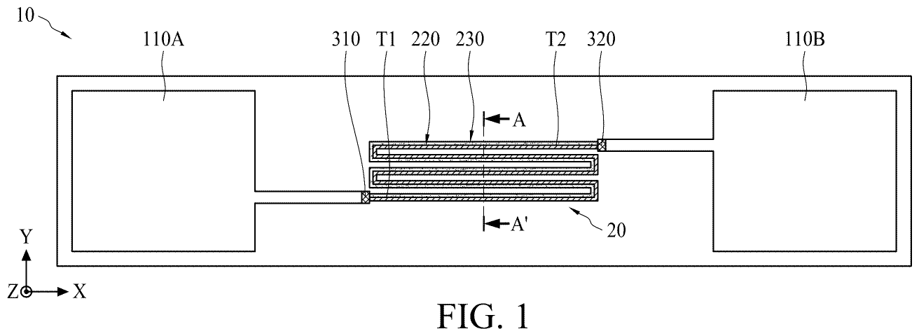

FIG. 1 is a schematic top view of a portion of a semiconductor device 10, in accordance with some embodiments of the present disclosure. Referring to FIG. 1, the semiconductor device 10 includes a resistive element 20 and various electronic components, such as a first electronic component 110A and a second electronic component 110B. The resistive element 20 may be disposed between the first electronic component 110A and the second electronic component 110B. The first and second electronic components 110A and 110B include active components (e.g., transistors, diodes, or the like) and/or passive components (e.g., capacitors, inductors, etc.).

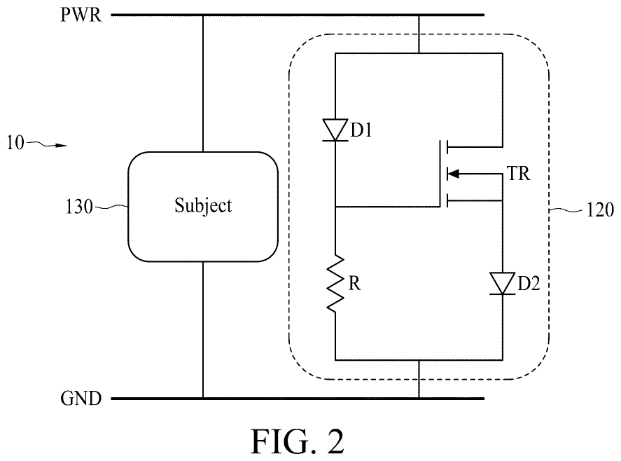

The semiconductor device 10 may include an electrostatic discharge (ESD) protection circuit 120 (as shown in FIG. 2) configured to protect a subject 130 when an ESD event occurs. Electrostatic discharge is the sudden discharge of electric charge between two electrically charged rails (e.g., a power supply rail PWR and a ground rail GND coupled to the semiconductor device 10). Such sudden discharge typically produces a large current that passed through the subject 130 in a short duration of time, which may result is damage or destruction of the subject 130, if not properly handled or protected. The ESD protection circuit 120 provides a current path to the power supply rail PWR or the ground rail GND when an ESD event occurs so that the large current resulting from the ESD event bypasses the subject 130 of the semiconductor device 10.

Referring to FIG. 2, the ESD protection circuit 120 includes a first diode D1, a second diode D2, a resistor R, and a transistor TR. An anode of the first diode D1 is coupled to the power rail PWR of the semiconductor device 10, and a cathode of the first diode D1 is coupled to a first terminal of the resistor R. A second terminal of the resistor R is coupled to the ground rail GND of the semiconductor device 10. The transistor TR is, for example, an n-type metal-oxide-semiconductor (NMOS) transistor. The transistor TR includes a drain coupled to the power rail PWR of the semiconductor device 10, a gate coupled to the cathode of the first diode D1 and the first terminal of the resistor R, and a source coupled to an anode of the second diode D2. A cathode of the second diode D2 is coupled to the ground rail GND of the semiconductor device 10. In some embodiments, the resistive element 20 shown in FIG. 1 is used as the resistor R of the ESD protection circuit 120. The first electronic component 110A and the second electronic component 110B shown in FIG. 1 may be used as any two of the first diode D1, the second diode D2, and the transistor TR of the ESD protection circuit 120.

Referring again to FIG. 1, the resistive element 20 has a first terminal T1 and a second terminal T2. In some embodiments, the resistive element 20 begins at the first terminal T1 and ends at the second terminal T2. The resistive element 20 may be coupled to a first contact pad 310 and a second contact pad 320. For example, the first terminal T1 of the resistive element 20 is connected to the first contact pad 310 that provides an electrical connection to the first electronic component 110A, and the second terminal T2 of the resistive element 20 is connected to the second contact pad 320 that provides an electrical connection to the second electronic component 110B. In some embodiments, the first contact pad 310 and the second contact pad 320 are on opposite sides of the resistive element 20, and the first contact pad 310 is offset from the second contact pad 320 in the Y-direction. In alternative embodiments, the first contact pad 310 and the second contact pad 320 are positioned on a same side or adjacent sides of the resistive element 20. In other alternative embodiments, the first contact pad 310 and the second contact pad 320 are on the opposite sides of the resistive element 20, and the first contact pad 310 is aligned with the second contact pad 320 in the Y-direction.

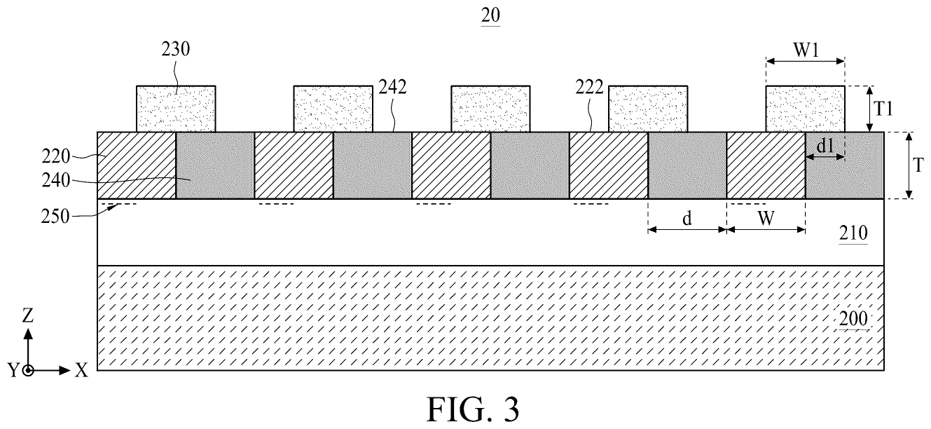

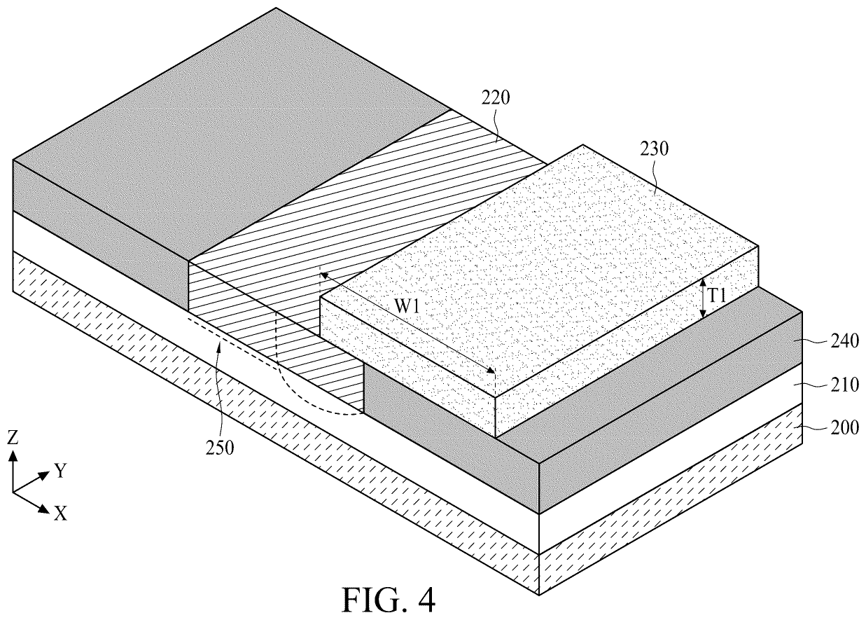

FIG. 3 is a schematic cross-sectional view along a line A-A′ of the semiconductor device 10 in FIG. 1, and FIG. 4 is a perspective view of a portion of the semiconductor device 10 in FIG. 1. Referring to FIGS. 3 and 4, in some embodiments, the resistive element 20 is a group III-V element including a heterojunction structure formed on a substrate 200. The resistive element 20 includes a first semiconductor layer 210, a second semiconductor layer 220, a third semiconductor layer 230, and an isolation feature 240. The second semiconductor layer 220 is disposed on the first semiconductor layer 210. In some embodiments, the second semiconductor layer 220 has a meandering serpentine-like pattern from a top-view perspective. The second semiconductor layer 220 may have an asymmetrical serpentine pattern from the top-view perspective (as shown in FIG. 1).

The third semiconductor layer 230 is disposed on the second semiconductor layer 220, and the third semiconductor layer 230 may at least partially overlap the second semiconductor layer 220. In some embodiments, the third semiconductor layer 230 is disposed along the second semiconductor layer 220, so that a pattern of the third semiconductor layer 230 is similar to or substantially same as the pattern of the second semiconductor layer 220 from the top-view perspective. The isolation feature 240 is disposed on the first semiconductor layer 210 to laterally surround the second semiconductor layer 220. In some embodiments, the isolation feature 240 has an upper surface 242 flush with an upper surface 222 of the second semiconductor layer 220. The isolation feature 240 may be an amorphous III-V compound layer.

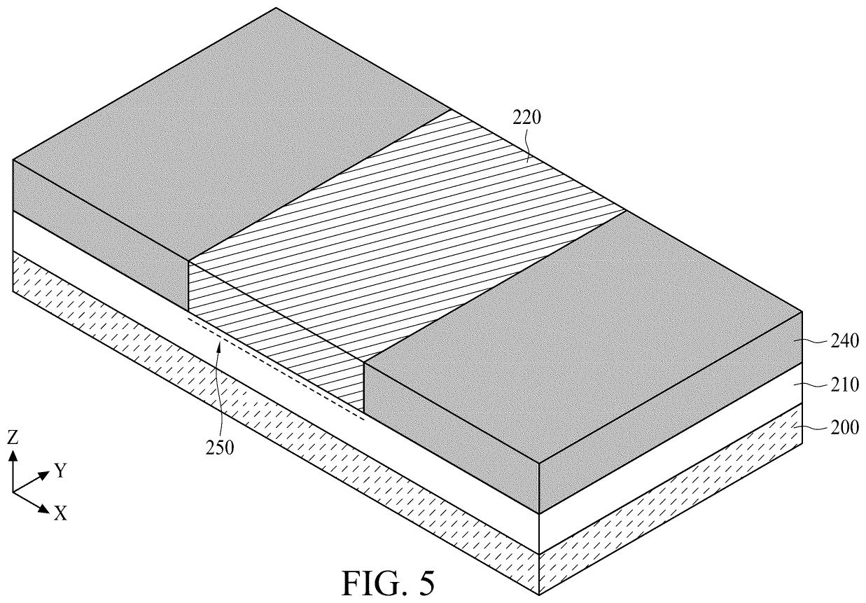

FIG. 5 is a perspective view of a portion of the substrate 200, the first semiconductor layer 210, the second semiconductor layer 220, and the isolation feature 240, in accordance with some embodiments of the present disclosure. In some embodiments, the first semiconductor layer 210 and the second semiconductor layer 220 include semiconductor materials with different bandgaps. For example, the first semiconductor layer 210 may have a bandgap lower than that of the second semiconductor layer 220. For example, the first semiconductor layer 210 includes a binary III-V semiconductor material, such as gallium nitride (GaN), and the second semiconductor layer 220 includes a ternary III-V semiconductor material, such as aluminum gallium nitride (AlGaN). Because the first semiconductor layer 210 and the second semiconductor layer 220 have materials with different bandgaps, a bandgap discontinuity exists between the first and second semiconductor layers 210 and 220, creating a carrier channel 250 of highly mobile conducting electrons in the first semiconductor layer 210. The carrier channel 250 is referred to as a two-dimensional electron gas (2DEG) channel, which is schematically illustrated. In some embodiments, the 2DEG channel is generated naturally in the first semiconductor layer 210 and near an interface between the first and second semiconductor layers 210 and 220, except in a region under the third semiconductor layer 230 where the 2DEG channel is partially or fully depleted, as will be described in more detail below.

In some embodiments, the first semiconductor layer 210 is made of GaN, and the second semiconductor layer 220, which overlies the first semiconductor layer 210, may be made of indium aluminum gallium nitride (InAlGaN), indium aluminum nitride (InAlN), aluminum nitride (AlN), aluminum indium nitride (AlInN), or the like. In other embodiments, the first semiconductor layer 210 is made of gallium arsenide (GaAs), and the second semiconductor layer 220, which overlies the first semiconductor layer 210, is made of aluminum gallium arsenide (AlGaAs), indium gallium phosphide (InGaP), indium gallium arsenide (InGaAs), or the like. In some embodiments, the resistive element 20 includes the first semiconductor layer 210 made of indium gallium arsenide (InGaAs) underlying the second semiconductor layer 220 made of aluminum gallium arsenide (AlGaAs), indium aluminum arsenide (InAlAs), or the like. The resistive element 20 may include the second semiconductor layer 220 made of indium arsenide (InAs) stacked on the first semiconductor layer 210 made of aluminum antimonide (AlSb). The resistive element 20 may include the second semiconductor layer 220 made of indium gallium arsenide (InGaAs) stacked on the first semiconductor layer 210 made of indium aluminum arsenide (InAlAs). The resistive element 20 may include the second semiconductor layer 220 made of cadmium tellurium (CdTe) stacked on the first semiconductor layer 210 made of lead telluride (PbTe).

In some embodiments, the first and third semiconductor layers 210 and 230 include substantially a same material, but have different doping concentrations. For example, the first semiconductor layer 210 is not doped with additional n-type dopant (such as phosphorous) and p-type dopant (such as boron), while the third semiconductor layer 230 is doped with appropriate dopant impurities. Accordingly, the n-type and p-type dopant concentration in the first semiconductor layer 210 may be equal to or close to zero, while the third semiconductor layer 230 has a doping concentration greater than that of the first semiconductor layer 210. The third semiconductor layer 230 may be, for example, a p-type doped binary III-V semiconductor layer.

In some embodiments, the second semiconductor layer 220 and the isolation feature 240 include substantially a same material, but have different doping concentrations. For example, the second semiconductor layer 220 is not doped with additional n-type dopant and p-type dopant, while the isolation feature 240 is doped with appropriate dopant impurities. Accordingly, the n-type and p-type dopant concentration in the second semiconductor layer 220 may be equal to or close to zero, while the isolation feature 240 has a doping concentration greater than that of the second semiconductor layer 220. The isolation feature 240 may be, for example, a p-type or n-type doped ternaryIII-V semiconductor layer.

The third semiconductor layer 230 may be used to deplete at least some carriers from the carrier channel 250 under a zero-bias condition. In some embodiments, the carriers in a region immediately under the third semiconductor layer 230 can be partially or fully depleted by the third semiconductor layer 230. In alternative embodiments, the third semiconductor layer 230 is used to deplete some or all carriers below the third semiconductor layer 230 (i.e., including the carriers in a first region immediately under the third semiconductor layer 230 and the carriers in a second region surrounding the first region).

Referring again to FIG. 3, in the cross-sectional view, the second semiconductor layer 220 has a thickness T and a width W, the third semiconductor layer 230 has a thickness T1 and a width W1, two adjacent second semiconductor layers 220 are spaced apart from one another by a distance d, and an overlap region of the third semiconductor layer 230 and the isolation feature 240 has a width d1. The width d1 of the overlap region may be less than about half the distance d.

In some embodiments, the resistive element 20 has an effective resistance that can be defined by the thickness T and the width W of the second semiconductor layer 220 and the thickness T1 and the width W1 of the third semiconductor layer 230. Specifically, the thickness T and the width W of the second semiconductor layer 220 and the thickness T1 and the width W1 of the third semiconductor layer 230 may be used to alter a carrier concentration in the first semiconductor layer 210, to thereby define the effective resistance of the resistive element 20. The effective resistance of the resistive element 20 may increase as the carrier concentration in the first semiconductor layer 210 decreases.

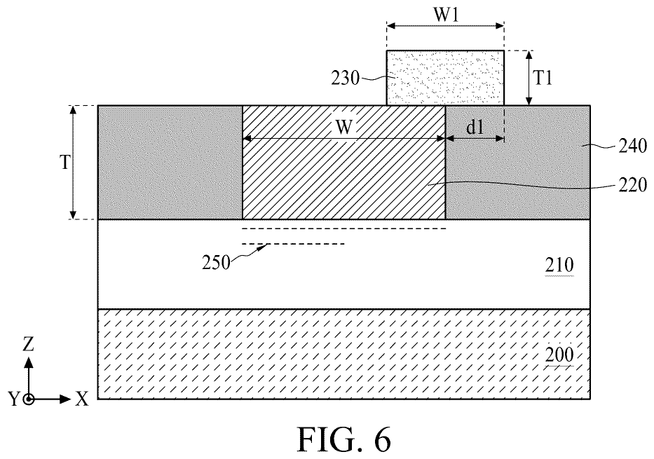

The carrier concentration in the carrier channel 250 may decrease due to an increase of the thickness T1 of the third semiconductor layer 230 and/or an increase of a size of an overlap region of the second and third semiconductor layers 220 and 230. In the illustrations referred to below, a thickness of a dashed line of the carrier channel 250 illustrates a concentration of the carriers within the first semiconductor layer 210. In an embodiment where the width W1 of the third semiconductor layer 230 is less than or equal to the width W of the second semiconductor layer 220, so that the third semiconductor layer 230 partially overlaps the second semiconductor layer 220, and where the thickness T1 of the third semiconductor layer 230 is less than about 0.1 times the thickness T of the second semiconductor layer 220, the carriers under the third semiconductor layer 230 are partially depleted from the first semiconductor layer 210, as shown in FIG. 6. The resistive element 20 that includes a configuration shown in FIG. 6 may be referred to as a partial depletion-mode resistive element.

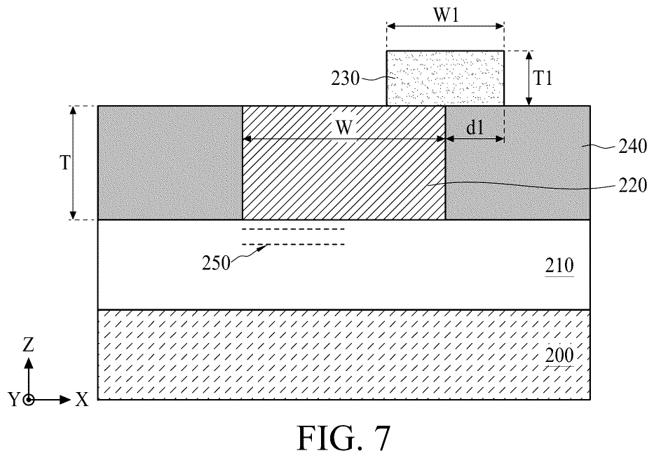

In an embodiment where the width W1 of the third semiconductor layer 230 is less than the width W of the second semiconductor layer 220, so that the third semiconductor layer 230 partially overlaps the second semiconductor layer 220, and where the thickness T1 of the third semiconductor layer 230 is greater than or equal to about 0.1 times the thickness T of the second semiconductor layer 220, the carriers under the third semiconductor layer 230 are fully depleted from the first semiconductor layer 210, as shown in FIG. 7. The resistive element 20 that includes a configuration shown in FIG. 7 may be referred to as a full depletion-mode resistive element. The partial depletion-mode resistive element shown in FIG. 6 may have an effective resistance less than an effective resistance of the full depletion-mode resistive element shown in FIG. 7.

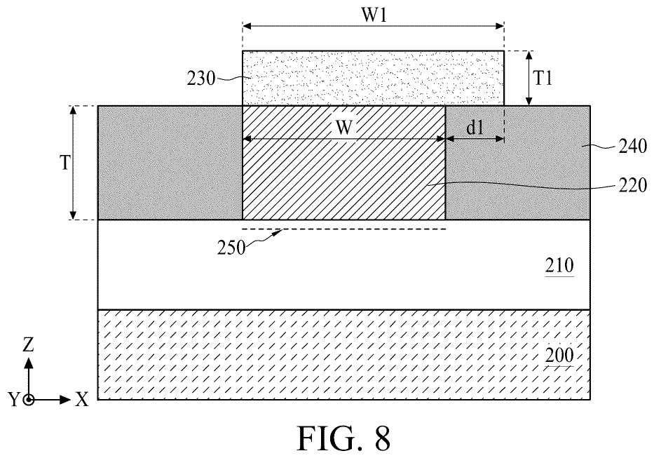

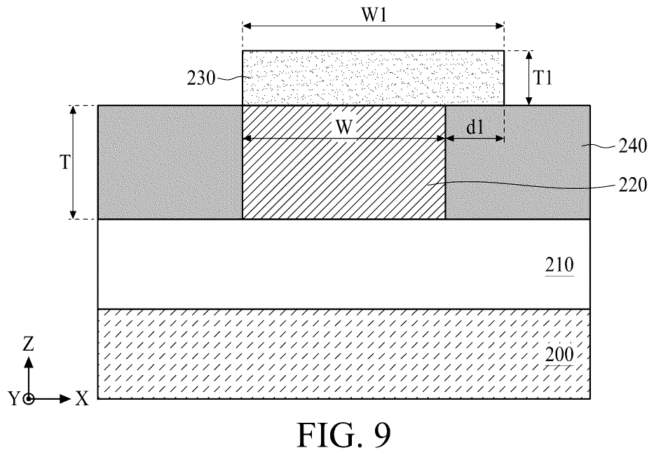

In an embodiment where the width W1 of the third semiconductor layer 230 is greater than the width W of the second semiconductor layer 220, so that the third semiconductor layer 230 fully overlaps the second semiconductor layer 220, and where the thickness T1 of the third semiconductor layer 230 is less than about 0.1 times the thickness T of the second semiconductor layer 220, the carriers under the third semiconductor layer 230 are partially depleted from the first semiconductor layer 210, as shown in FIG. 8. In an embodiment where the width W1 of the third semiconductor layer 230 is greater than the width W of the second semiconductor layer 220, and the thickness T1 of the third semiconductor layer 230 is greater than or equal to about 0.1 times the thickness T of the second semiconductor layer 220, all of the carriers are depleted from the first semiconductor layer 210, as shown in FIG. 9. The resistive element 20 that includes a configuration shown in FIG. 8 or 9 may be referred to as a shunt-mode resistive element. The shunt-mode resistive element shown in FIG. 9 may have an effective resistance greater than that of the shunt-mode resistive element shown in FIG. 8. The effective resistance of the full depletion-mode resistive element shown in FIG. 7 may be less than the effective resistance of the shunt-mode resistive element shown in FIG. 9.

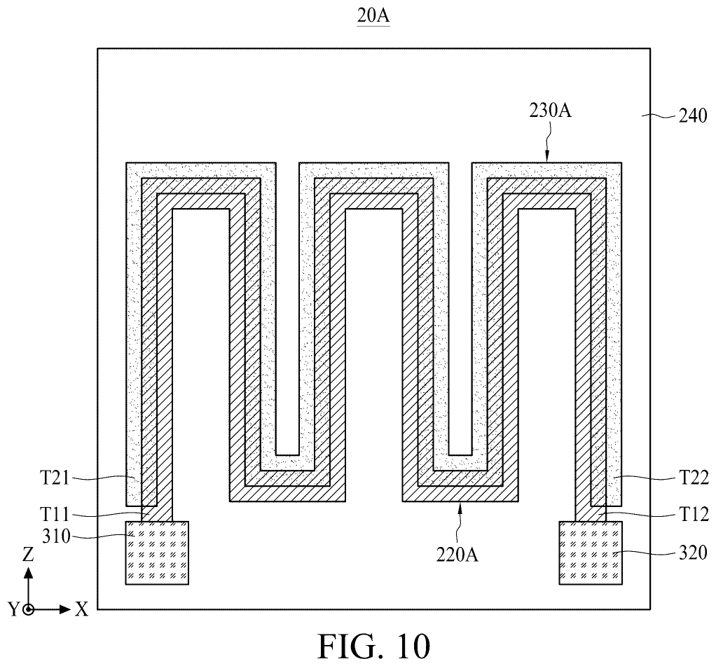

FIG. 10 is a schematic top view of a resistive element 20A, in accordance with some embodiments of the present disclosure. The resistive element 20A is similar to the resistive element 20 discussed above, except that the second semiconductor layer 220 and the third semiconductor layer 230 are replaced by a second semiconductor layer 220A and a third semiconductor layer 230A, respectively, and the resistive element 20A includes an arrangement of the first and second contact pads 310 and 320 different from that in the resistive element 20. Referring to FIG. 10, the second semiconductor layer 220A and the third semiconductor layer 230A may have an asymmetrical serpentine pattern from a top-view perspective, wherein the second semiconductor layer 220A and the third semiconductor layer 230A at least partially overlap. The second semiconductor layer 220A is laterally surrounded by the isolation feature 240.

The first contact pad 310 and the second contact pad 320 are disposed at a same side of the resistive element 20A. In some embodiments, the second semiconductor layer 220A includes a first terminal T11 and a second terminal T12, wherein the first terminal T11 and the second terminal T12 are electrically connected to a first contact pad 310 and a second contact pad 320, respectively. In some embodiments, the third semiconductor layer 230A has a first terminal T21 and a second terminal T22; the first terminal T21 is spaced apart from the first contact pad 310, and the second terminal T22 is spaced apart from the second contact pad 320. The first and second terminals T21 and T22 of the third semiconductor layer 230A may be separated from the first contact pad 310 and the second contact pad 320. In some embodiments, the first and second terminals T21 and T22 are electrically and/or physically isolated from other electronic components.

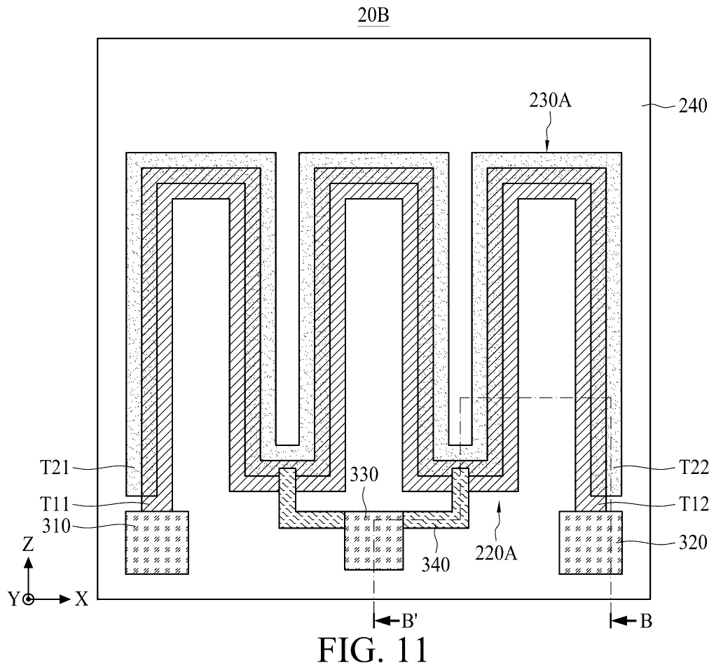

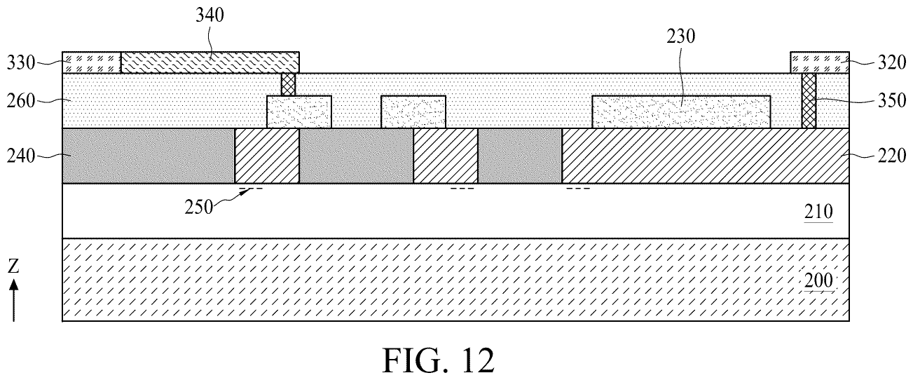

FIG. 11 is a schematic top view of a resistive element 20B, in accordance with some embodiments of the present disclosure, and FIG. 12 is a schematic cross-sectional view taken along a line B-B′ of the semiconductor device in FIG. 11. The resistive element 20B is similar to the resistive element 20A discussed above, except that the resistive element 20B includes an passivation layer 260, at least one control pad 330, one or more connecting lines 340, and a plurality of conductive vias 350. Referring to FIGS. 11 and 12, the passivation layer 260 is disposed over the second semiconductor layer 220 and the isolation feature 240 and surround the third semiconductor layer 230. In some embodiments, the passivation layer 260 includes dielectric material, such as an oxide.

The control pad 330 and the connecting lines 340 may be disposed on the passivation layer 250, and the connecting lines 340 are physically connected to the control pad 330. The connecting lines 340 and the third semiconductor layer 230 disposed at different vertical level are electrically to each other by at least one of the conductive vias 350. The first contact pad 310 and the second contact pad 320 may be disposed on the passivation layer 250 and electrically connected to the second semiconductor layer 220 by one or more conductive vias 350. The control pad 330 may be made of metal, such as copper, aluminum, or the like. In some embodiment, the first contact pad 310, the second contact pad 320, the connecting lines 340 and the conductive vias 350 may include a material same as a material of the control pad 330, such that the connecting lines 340 and the conductive vias 350 may be formed simultaneously with the control pad 330. Damascene operations may be utilized to form the first contact pad 310, the second contact pad 320, the control pad 330, the connecting lines 340, and the conductive vias 350.

In some embodiments, a positive bias or a negative bias can be applied to the control pad 330 to alter an effective resistance of the resistive element 20B. The positive bias may increase carriers created in a first semiconductor layer 210 underlying the second semiconductor layer 220A, to thereby decrease the effective resistance of the resistive element 20B. On the other hand, the negative bias may decrease carriers created in the first semiconductor layer 210, to thereby increase the effective resistance of the resistive element 20B.

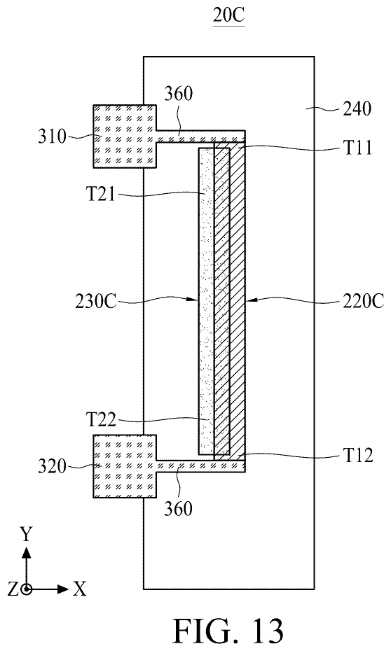

FIG. 13 is a schematic top view of a resistive element 20C, in accordance with some embodiments of the present disclosure. The resistive element 20C is similar to the resistive element 20 discussed above, except that the second semiconductor layer 220 and the third semiconductor layer 230 of the resistive element 20 are replaced by a second semiconductor layer 220C and a third semiconductor layer 230C, respectively, and the resistive element 20C also includes a pair of interconnect members 360. Referring to FIG. 13, the second semiconductor layer 220C and the third semiconductor layer 230C may have a straight pattern from the top-view perspective, wherein the second semiconductor layer 220C and the third semiconductor layer 230C at least partially overlap. The second semiconductor layer 220C is laterally surrounded by the isolation feature 240.

In some embodiments, the second semiconductor layer 220C includes a first terminal T11 and a second terminal T12. One of the interconnect members 360 extends to overlap the first terminal T11 of the second semiconductor layer 220C, and another of the interconnect members 360 extends to overlap the second terminal T12 of the second semiconductor layer 220C. The interconnect members 360 and the second semiconductor layer 220C may be disposed at different levels of the resistive element 20C, from a cross-sectional perspective, and the interconnect members 360 may be electrically connected to the second semiconductor layer 220 by conductive vias (not shown). The interconnect members 360 may include a material same as a material of the first contact pad 310 and the second contact pad 320. The third semiconductor layer 230C has a first terminal T21 and a second terminal T22 which may be spaced apart from the interconnect members 360 to prevent electrical connection therebetween. In some embodiments, the first and second terminals T21 and T22 are electrically and/or physically isolated from other electronic components.

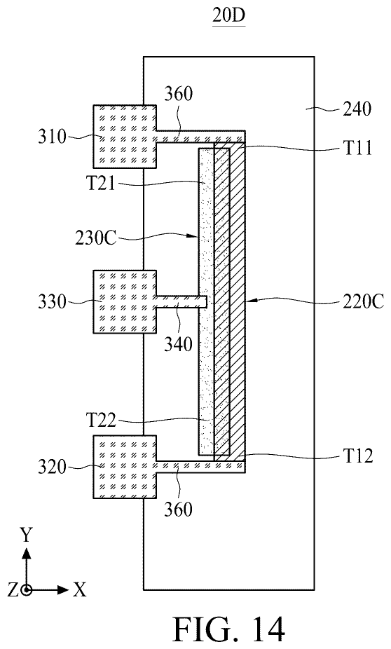

FIG. 14 is a schematic top view of a resistive element 20D, in accordance with some embodiments of the present disclosure. The resistive element 20D is similar to the resistive element 20C discussed above, except that the resistive element 20D includes a control pad 330 and a connecting line 340. Referring to FIG. 14, the connecting line 340 may be physically connected to the control pad 330 and extend to overlap the third semiconductor layer 230. In some embodiments, the connecting line 340 is electrically connected to the third semiconductor layer 230 by one or more conductive vias (not shown). The connecting line 340 may include a material same as a material of the control pad 330. In some embodiments, a positive bias or a negative bias can be applied to the control pad 330 to alter an effective resistance of the resistive element 20D. The positive bias may increase a concentration of the 2DEG in a first semiconductor layer 210 underlying the second semiconductor layer 220C, to thereby decrease the effective resistance of the resistive element 20D. Alternatively, the negative bias may deplete carriers in the carrier channel, to thereby increase the effective resistance of the resistive element 20D.

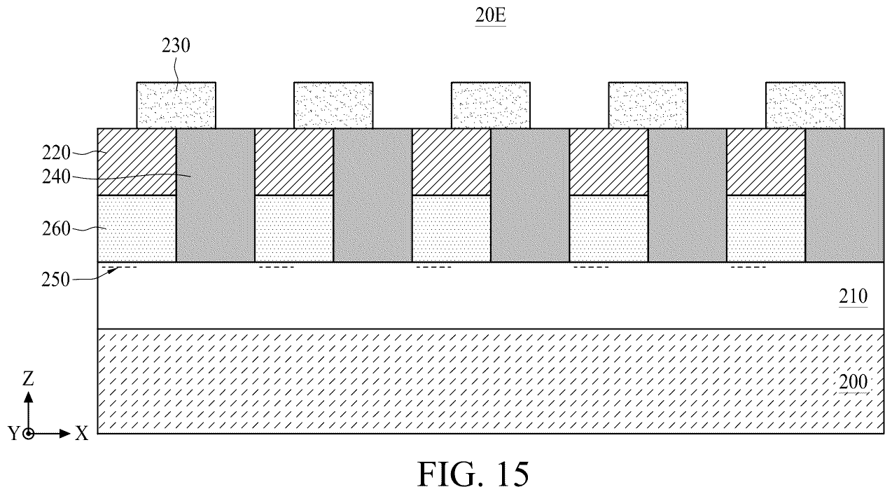

In some embodiments, a resistive element 20E, as shown in FIG. 15, has a substrate 200, a first semiconductor layer 210, a second semiconductor layer 220, a third semiconductor layer 230, an isolation feature 240, and a fourth semiconductor layer 260. The first semiconductor layer 210 is disposed on the substrate 200. The fourth semiconductor layer 260 may be disposed on the first semiconductor layer 210. The second semiconductor layer 220 is stacked on the fourth semiconductor layer 260.

The second semiconductor layer 220 and the fourth semiconductor layer 260 are laterally surrounded by the isolation feature 240. The third semiconductor layer 230 is disposed over the second semiconductor layer 220 and the isolation feature 240. The third semiconductor layer 230 may partially overlap with the second semiconductor layer 220 and the isolation feature 240. In some embodiments, the first semiconductor layer 210 is made of GaN, the second semiconductor layer 220 is made of AlGaN, and the fourth semiconductor layer 260 is made of aluminum nitride (AlN) or InAlN. The isolation feature 240 may be an amorphous III-V compound layer.

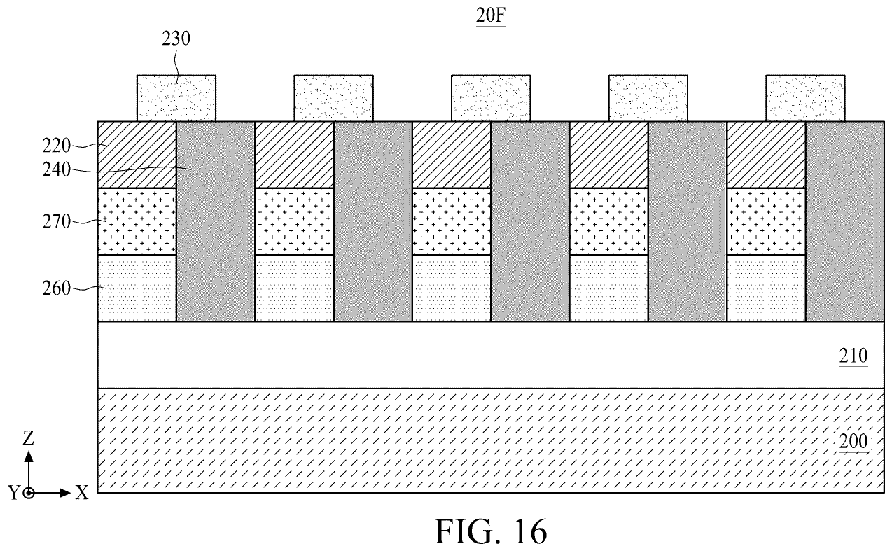

In some embodiments, a resistive element 20F, as shown in FIG. 16, has a substrate 200, a first semiconductor layer 210, a second semiconductor layer 220, a third semiconductor layer 230, an isolation feature 240, a fourth semiconductor layer 260, and a fifth semiconductor layer 270. The first semiconductor layer 210 is disposed on the substrate 200. In some embodiments, the first semiconductor layer 210 is disposed on an entirety of an upper surface of the substrate 200. The fourth semiconductor layer 260 and the fifth semiconductor layer 270 are sequentially disposed on the first semiconductor layer 210. The second semiconductor layer 220 is stacked on the fifth semiconductor layer 270. The isolation feature 240 is disposed on the first semiconductor layer 210, and the second semiconductor layer 220, the fourth semiconductor layer 260, and the fifth semiconductor layer 270 are laterally surrounded by the isolation feature 240. The third semiconductor layer 230 is disposed over the second semiconductor layer 220 and the isolation feature 240. The third semiconductor layer 230 may partially overlap the second semiconductor layer 220 and the isolation feature 240. In some embodiments, the first and fifth semiconductor layers 210 and 270 are made of GaN, the second semiconductor layer 220 is made of AlGaN, and the fourth semiconductor layer 260 is made of indium gallium nitride (InGaN). The isolation feature 240 may be an amorphous III-V compound layer.

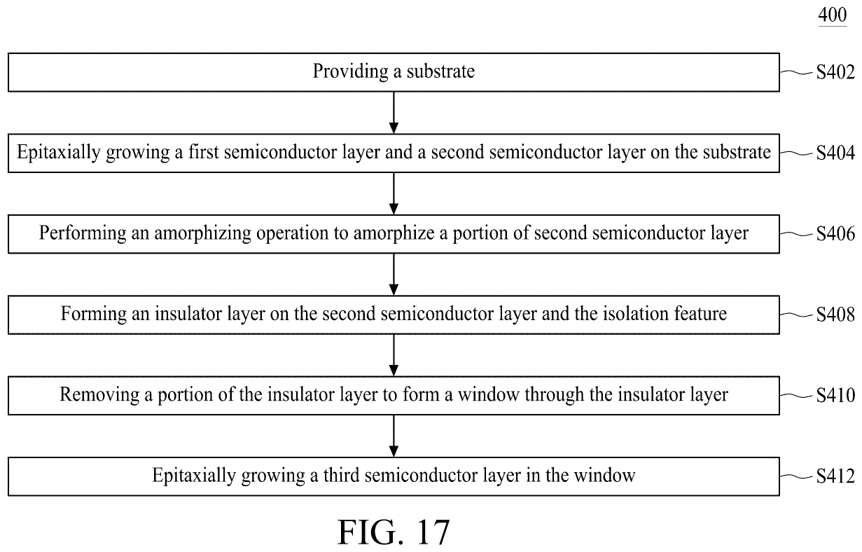

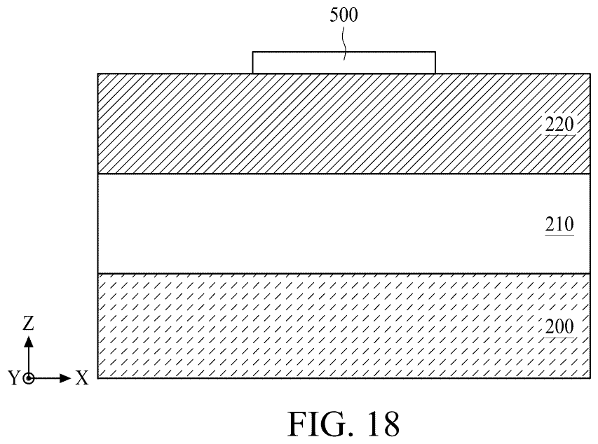

FIG. 17 is a flowchart of a method 400 of manufacturing a resistive element 20, in accordance with some embodiments of the present disclosure. FIGS. 18 to 22 are cross-sectional views of intermediate stages of the method 400 of manufacturing the resistive element 20, in accordance with some embodiments of the present disclosure. In the following description, the manufacturing stages shown in FIGS. 18 to 22 are discussed with reference to the process steps shown in FIG. 17. It should be understood that additional steps can be provided before, during, and after the steps shown in FIG. 17, and some of the steps described below can be replaced or eliminated, for additional embodiments of the method 400. The order of the steps may be changed.

Referring to FIGS. 17 and 18, a substrate 200 is provided in accordance with step S402. The substrate 200 may be a part of a wafer or a bulk substrate formed of bulk material. In some embodiments, the substrate 200 includes a silicon substrate, a silicon carbide (SiC) substrate, a sapphire substrate, or the like. In some embodiments, the substrate 200 is a silicon substrate. Alternative substrate materials, such as sapphire and silicon carbide, may be used for GaN devices.

Subsequently, a first semiconductor layer 210 and a second semiconductor layer 220 are epitaxially grown on the substrate 200 in accordance with step S404 in FIG. 17. The first semiconductor layer 210 and the second semiconductor layer 220 are sequentially stacked on the substrate 200. In some embodiments, the first semiconductor layer 210 is made of a material having a first bandgap, and the second semiconductor layer 220 is made of a material having a second bandgap greater than the first bandgap. For example, the first semiconductor layer 210 includes GaN, and the second semiconductor layer 220 includes AlGaN. The first semiconductor layer 210 and the second semiconductor layer 220 together form a heterojunction. Each of the first semiconductor layer 210 and the second semiconductor layer 220 is grown on the substrate 200 using a suitable growth technique. For example, each of the first semiconductor layer 210 and the second semiconductor layer 220 is grown using a metal-organic chemical vapor deposition (MOCVD) operation and a molecular beam epitaxy (MBE) operation.

After the formation of the second semiconductor layer 220, a mask layer 500 is disposed over the second semiconductor layer 220. In some embodiments, one or more portions of the second semiconductor layer 220 are covered by the mask layer 500 to define a desired pattern of the resistive element 20.

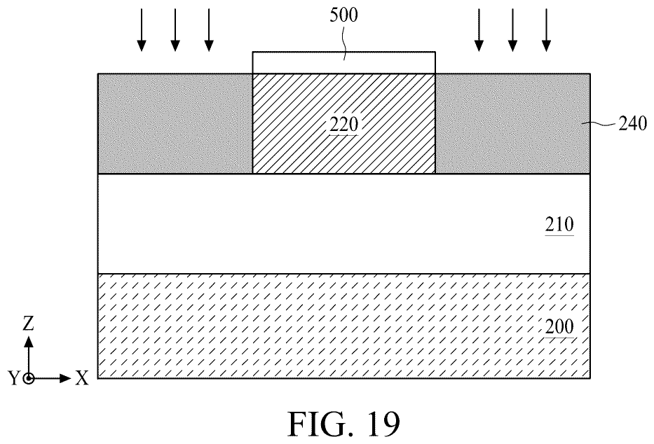

Referring to FIG. 19, an amorphizing operation is performed to amorphize at least a portion of the second semiconductor layer 220 not protected by the mask layer 500 in accordance with step S406 in FIG. 17. Accordingly, an isolation feature 240 is formed. In some embodiments, the amorphizing operation includes performing an implantation process to introduce impurities into the portion of the second semiconductor layer 220. The impurities may include nitrogen, argon, carbon, fluorine or a combination thereof. In some embodiments, the second semiconductor layer 220 and the isolation feature 240 have substantially a same composition. In some embodiments, the implantation operation is performed, for example but not limited thereto, at an energy of about 1 KeV to 600 KeV and a dose of about 1012 atoms/cm³ to 1016 atoms/cm³. After the amorphizing operation, the mask layer 500 is removed using suitable operations. After the isolation feature 240 is formed, the mask layer 500 is removed using a suitable removal process.

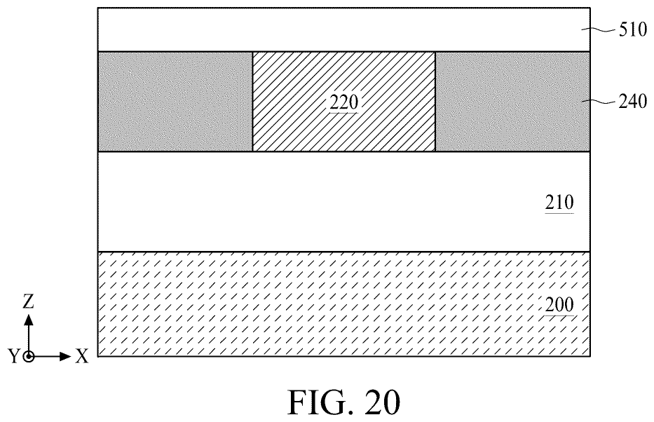

Referring to FIG. 20, an insulator layer 510 is formed on the second semiconductor layer 220 and the isolation feature 240 in accordance with step S408 in FIG. 17. In some embodiments, the insulator layer 510 includes an oxide (such as silicon oxide), a nitride (such as silicon nitride), or an oxynitride (such as silicon oxynitride). In some embodiments, the insulator layer 510 completely covers upper surfaces of the second semiconductor layer 220 and the isolation feature 240. In some embodiments, the insulator layer 510 including the oxide is formed on the second semiconductor layer 220 and the isolation feature 240 by performing a thermal oxidization operation or chemical vapor deposition (CVD). The insulator layer 510 including the nitride or the oxynitride may be deposited on the second semiconductor layer 220 and the isolation feature 240 by low-pressure chemical vapor deposition (LPCVD) or plasma-enhanced chemical vapor deposition (PECVD).

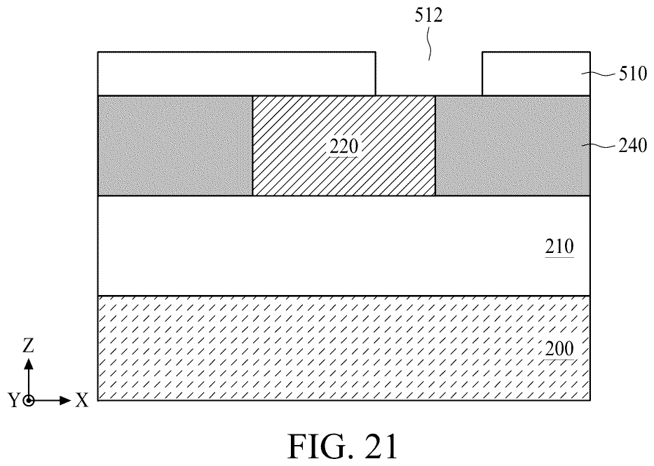

Referring to FIG. 21, a portion of the insulator layer 510 is removed in accordance with step S410 in FIG. 17. Accordingly, a window 512 is formed through the insulator layer 510 to expose a portion of the second semiconductor layer 220 and a portion of the isolation feature 240 adjacent to the portion of the second semiconductor layer 220. In some embodiments, the portion of the insulator layer 510 is removed using an etching operation.

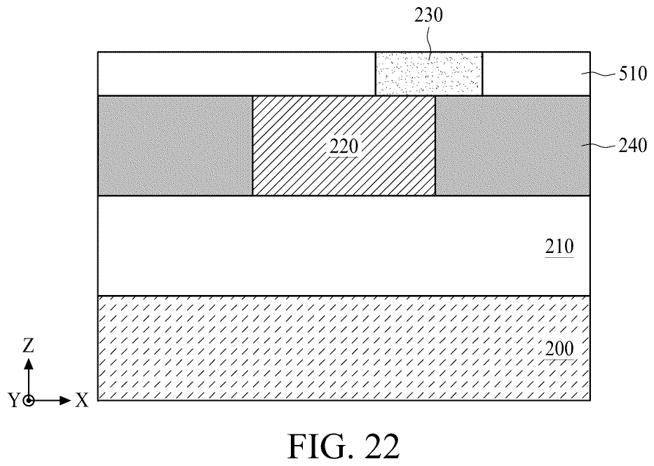

Referring to FIG. 22, a third semiconductor layer 230 is epitaxially grown in the window 512 in accordance with step S412 in FIG. 17. Consequently, the resistive element 20 is completely formed. The third semiconductor layer 230 is epitaxially grown until the window 512 is entirely filled. The third semiconductor layer 230 may include p-doped GaN. The third semiconductor layer 230 may be grown using a MOCVD operation and an MBE operation. In some embodiments, the third semiconductor layer 230 can be planarized, such as by a chemical mechanical polishing (CMP) operation, to have a planar top surface. The insulator layer 510 is removed from the second semiconductor layer 220 and the isolation feature 240 after the third semiconductor layer 230 is completely formed.

In accordance with some embodiments of the present disclosure, a semiconductor component includes: a first semiconductor layer comprising a first material having a first bandgap; a second semiconductor layer disposed on the first semiconductor layer, wherein the second semiconductor layer comprises a second material having a second bandgap, wherein the second bandgap is greater than the first bandgap, thus forming a carrier channel in the first semiconductor layer; and a third semiconductor layer at least partially overlapping the second semiconductor layer, wherein the first semiconductor layer and the third semiconductor layer have a same material, but have different doping concentrations.

In accordance with some embodiments of the present disclosure, a semiconductor device comprises a semiconductor structure, a first contact pad electrically coupled to one terminal of the semiconductor structure, and a second contact pad electrically coupled to another terminal of the semiconductor structure. The semiconductor structure includes a first semiconductor layer comprising a first material having a first bandgap; a second semiconductor layer disposed on the first semiconductor layer, wherein the second semiconductor layer comprises a second material having a second bandgap, wherein the second bandgap is greater than the first bandgap, thus forming a carrier channel in the first semiconductor layer; and a third semiconductor layer at least partially overlapping the second semiconductor layer, wherein the first semiconductor layer and the third semiconductor layer have a same material, but have different doping concentrations.

In accordance with some embodiments of the present disclosure, a method of forming a semiconductor structure comprises steps of depositing a first semiconductor layer on a substrate; depositing a second semiconductor layer on the first semiconductor layer; performing an amorphizing operation to amorphize at least a portion of second semiconductor layer to form an isolation feature laterally surrounding a remaining second semiconductor layer; and depositing a third semiconductor layer at least partially overlapping the remaining second semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor layer comprising a first material having a first bandgap;
a second semiconductor layer disposed on the first semiconductor layer, wherein the second semiconductor layer comprises a second material having a second bandgap, wherein the second bandgap is greater than the first bandgap; and
a third semiconductor layer at least partially overlapping the second semiconductor layer,
wherein the first semiconductor layer and the third semiconductor layer have a same material, but have different doping concentrations.

2. The semiconductor structure of claim 1, further comprising an isolation feature disposed on the first semiconductor layer to laterally surround the second semiconductor layer, wherein the third semiconductor layer partially overlaps the isolation feature.

3. The semiconductor structure of claim 2, wherein the second semiconductor layer and the isolation feature have a same material, but have different doping concentrations.

4. The semiconductor structure of claim 2, wherein an upper surface of the second semiconductor layer is flush with an upper surface of the isolation feature.

5. The semiconductor structure of claim 1, wherein the third semiconductor layer fully overlaps the second semiconductor layer.

6. The semiconductor structure of claim 1, further comprising:
a control pad; and
a connecting line connecting the third semiconductor layer to the control pad,
wherein a bias is applied to the control pad to alter an effective resistance of the semiconductor structure.

7. The semiconductor structure of claim 6, wherein the third semiconductor layer and the connecting line comprise a same material.

8. The semiconductor structure of claim 1, wherein a dopant concentration in the first semiconductor layer is equal to or close to zero.

9. The semiconductor structure of claim 1, wherein the second semiconductor layer and the third semiconductor layer have a substantially same pattern from a top-view perspective.

10. The semiconductor structure of claim 1, wherein the second semiconductor layer has an asymmetrical serpentine pattern, a symmetrical serpentine pattern, or a straight pattern from a top-view perspective.

11. The semiconductor structure of claim 1, where the third semiconductor layer is a p-type doped binary III-V semiconductor layer.

12. A semiconductor device, comprising:
a semiconductor structure comprising:
a first semiconductor layer comprising a first material having a first bandgap;
a second semiconductor layer disposed on the first semiconductor layer, wherein the second semiconductor layer comprises a second material having a second bandgap, wherein the second bandgap is greater than the first bandgap, thus forming a carrier channel in the first semiconductor layer; and
a third semiconductor layer at least partially overlapping the second semiconductor layer,
wherein the first semiconductor layer and the third semiconductor layer have a same material, but have different doping concentrations,
a first contact pad electrically coupled to a first terminal of the semiconductor structure; and
a second contact pad electrically coupled to a second terminal of the semiconductor structure.

13. The semiconductor device of claim 12, wherein the second semiconductor layer begins at the first contact pad and ends at the second contact pad.

14. The semiconductor device of claim 12, wherein the third semiconductor layer begins at a third terminal and ends at a fourth terminal, wherein the third terminal of the third semiconductor layer is spaced apart from the first contact pad and the fourth terminal of the third semiconductor layer is spaced apart from the second contact pad.

15. The semiconductor device of claim 12, further comprising a plurality of interconnect members, wherein one of the interconnect members connects the first terminal of the semiconductor structure to the first contact pad, and another of the interconnect members connects the second terminal of the semiconductor structure to the second contact pad.

16. The semiconductor device of claim 12, wherein the first contact pad and the second contact pad are disposed at opposite sides of the semiconductor structure.

17. A method of forming a semiconductor structure, comprising:
depositing a first semiconductor layer on a substrate;
depositing a second semiconductor layer on the first semiconductor layer;
performing an amorphizing operation to amorphize a portion of the second semiconductor layer to form an isolation feature laterally surrounding a remaining second semiconductor layer; and
depositing a third semiconductor layer at least partially overlapping the remaining second semiconductor layer.

18. The method of claim 17, wherein the deposition of the third semiconductor layer comprises:
forming an insulator layer on the remaining second semiconductor layer and the isolation feature;
forming a window in the insulator layer to expose a first portion of the remaining second semiconductor layer and a second portion of the isolation feature, wherein the first portion of the second semiconductor layer is adjacent to the second portion of the isolation feature; and
depositing the third semiconductor layer in the window.

19. The method of claim 18, wherein the insulator layer is formed by oxidizing the second semiconductor layer and the isolation feature.

20. The method of claim 17, wherein the amorphizing operation comprises performing an implantation process to introduce impurities into the second semiconductor layer.
